(19) United States
(12) Patent Application Publication
(10) Pub. No.: US 2023/0093323 A1
(43) Pub. Date: Mar. 23, 2023

(54) FILM FORMING APPARATUS, FILM FORMING METHOD, AND FILM FORMING SYSTEM

(71) Applicant: Tokyo Electron Limited, Tokyo (JP)

(72) Inventors: Tadahiro ISHIZAKA, Nirasaki City (JP); Masayuki MOROI, Nirasaki City (JP); Yuichi FURUYA, Nirasaki City (JP)

(21) Appl. No.: 17/930,794

(22) Filed: Sep. 9, 2022

(30) Foreign Application Priority Data
Sep. 21, 2021 (JP) 2021-153188

(51) Int. Cl. C23C 16/04; C23C 16/02; C23C 16/06; C23C 16/44; C23C 16/56; C23C 16/52

(52) U.S. Cl. CPC C23C 16/045; C23C 16/0227; C23C 16/06; C23C 16/4412; C23C 16/56; C23C 16/52

(57) ABSTRACT

A film forming apparatus embeds ruthenium in a substrate having a recess. The film forming apparatus includes: a processing container; a gas supplier configured to supply gas; and a gas exhauster configured to exhaust gas, wherein the gas supplier includes a first supply line configured to supply a ruthenium raw-material gas into the processing container and a second supply line configured to supply a gas containing ozone gas into the processing container, and wherein the gas exhauster includes a first exhaust line including a first exhaust apparatus and configured to exhaust a gas containing a ruthenium raw-material gas from an interior of the processing container by using the first exhaust apparatus, and a second exhaust line including a second exhaust apparatus different from the first exhaust apparatus and configured to exhaust the gas containing ozone gas by using the second exhaust apparatus.

### CROSS-REFERENCE TO RELATED APPLICATION

This application is based upon and claims the benefit of priority from Japanese Patent Application No. 2021-153188, filed on Sep. 21, 2021, the entire contents of which are incorporated herein by reference.

### TECHNICAL FIELD

The present disclosure relates to a film forming apparatus, a film forming method, and a film forming system.

### BACKGROUND

Low-resistance ruthenium (Ru) is attracting attention as a material for minute shapes of wires for interconnecting transistors, contacts, and the like formed on a substrate. For example, Patent Documents 1 and 2 propose a technique for embedding ruthenium in a recess formed in a substrate. In order to realize low resistance wires and contacts, it is important to embed ruthenium in recesses without generating voids that increase resistance.

### PRIOR ART DOCUMENT

### Patent Document

Patent Document 1: Japanese Laid-Open Publication No. 2018-147949
Patent Document 2: Japanese Laid-Open Publication No. 2020-47864

### SUMMARY

According to one embodiment of the present disclosure, there is provided a film forming apparatus that embeds ruthenium in a substrate having a recess. The film forming apparatus includes: a processing container; a gas supplier configured to supply gas; and a gas exhauster configured to exhaust gas. The gas supplier includes a first supply line configured to supply a ruthenium raw-material gas into the processing container and a second supply line configured to supply a gas containing ozone gas into the processing container. The gas exhauster includes a first exhaust line including a first exhaust apparatus and configured to exhaust a gas containing a ruthenium raw-material gas from an interior of the processing container by using the first exhaust apparatus, and a second exhaust line including a second exhaust apparatus different from the first exhaust apparatus and configured to exhaust the gas containing ozone gas by using the second exhaust apparatus.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view illustrating an example of a film forming system according to an embodiment.

FIG. 2 is a schematic cross-sectional view illustrating an example of a film forming apparatus according to an embodiment.

FIG. 3 is a flowchart illustrating an example of a film forming method according to an embodiment.

FIGS. 4A to 4D are cross-sectional views illustrating a recess in a substrate in the film forming method of FIG. 3.

FIGS. 5A to 5C are views showing the configuration and operation of a film forming apparatus according to a first embodiment.

FIGS. 6A to 6C are schematic views illustrating chemical reactions that occur in the film forming method of FIG. 3.

FIGS. 7A to 7C are views illustrating the configuration and operation of a film forming apparatus according to a second embodiment.

FIGS. 8A to 8C are views illustrating the configuration and operation of a film forming apparatus according to a third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each of the drawings, the same components may be denoted by the same reference numerals, and redundant descriptions thereof may be omitted.

### [Film Forming System]

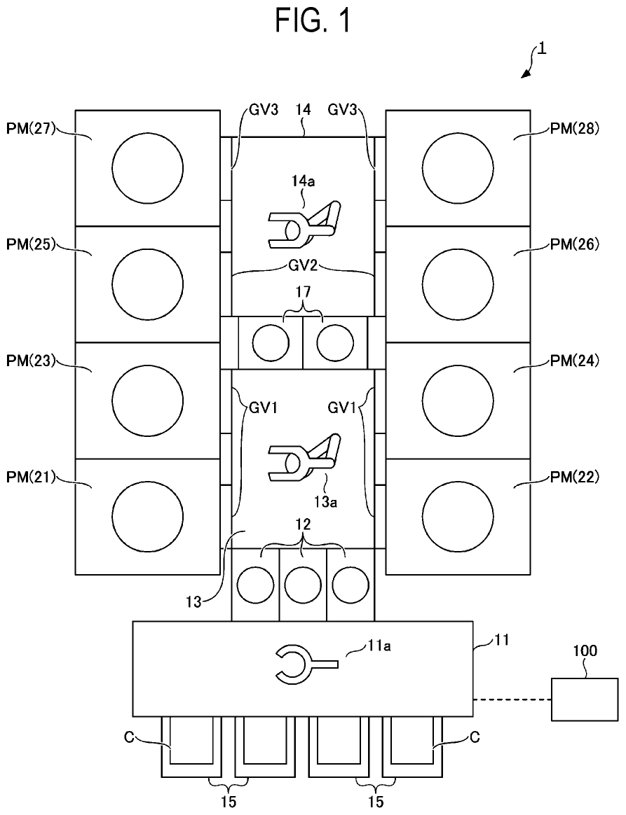

First, the configuration and operation of a film forming system 1 according to an embodiment will be described with reference to FIG. 1. FIG. 1 is a schematic plan view illustrating an example of a film forming system according to an embodiment. The film forming system 1 executes a process including a process of embedding ruthenium in a recess formed on a substrate.

The film forming system 1 includes an atmospheric transport chamber 11, load-lock chambers 12, a first substrate transport chamber 13, a second substrate transport chamber 14, and processing chambers PM. In FIG. 1, the processing chambers PM include pre-cleaning apparatuses 21 and 22, film forming apparatuses 23 to 27, and an annealing apparatus 28. However, when a substrate is not annealed, the processing chambers PM may include pre-cleaning apparatuses and film forming apparatuses. The film forming apparatuses may include a film forming apparatus for embedding ruthenium in a recess formed in a substrate and a film forming apparatus for laminating ruthenium in which ruthenium is further laminated on the embedded ruthenium to form a flat ruthenium layer.

The numbers and arrangements of pre-cleaning apparatuses, film forming apparatuses, and annealing apparatuses are not limited to the example illustrated in FIG. 1, and the numbers and arrangements of respective apparatuses may be set to improve the overall throughput. For example, when a ruthenium embedding process takes time and the annealing process is not required, two pre-cleaning apparatuses, five film forming apparatuses for embedding ruthenium, and one film forming apparatus for laminating ruthenium may be prepared and arranged at appropriate positions of eight processing chambers PM. When an annealing process is required after film formation for laminating ruthenium, two pre-cleaning apparatuses, three film forming apparatuses for embedding ruthenium, one film forming apparatus for laminating ruthenium, and two annealing apparatuses may be provided and arranged at appropriate positions of eight processing chambers PM.

The first substrate transport chamber 13 and the second substrate transport chamber 14 are each configured in a square shape in a plan view, and are connected to each other via, for example, two delivery parts 17. The interiors of the first and second substrate transport chambers 13 and 14 and the delivery parts 17 are set to a vacuum pressure atmosphere and configured to have uniform pressures. The delivery parts 17 perform substrate delivery to and from a first transport mechanism 13a installed in the first substrate transport chamber 13 or to and from a second transport mechanism 14a installed in the second substrate transport chamber 14. The first substrate transport chamber 13 and the second substrate transport chamber 14 each include a turbo molecular pump (not illustrated) for a transport chamber to control the interior of each transport chamber to a desired pressure.

It is assumed that the direction in which the first substrate transport chamber 13 and the second substrate transport chamber 14 are arranged is referred to as a length direction, and that the first substrate transport chamber 13 is on the front side and the second substrate transport chamber 14 is on the rear side. At this time, the atmosphere transport chamber 11 set to the atmospheric pressure atmosphere is connected to the front side of the first substrate transport chamber 13 via, for example, three load-lock chambers 12. There are transport ports and gate valves for opening/closing the transport ports are provided, respectively, between the first and second substrate transport chambers 13 and 14 and the delivery parts 17, between the load-lock chambers 12 and the first substrate transport chamber 13, and between the load-lock chambers 12 and the atmospheric transport chamber 11, but the illustration thereof is omitted.

For example, four load ports 15 are connected to the atmospheric transport chamber 11, and a carrier C accommodating plural sheets of substrates is placed in each load port 15. An atmospheric transport mechanism 11a is installed in the atmospheric transport chamber 11 to transport substrates between the carriers C connected to the atmospheric transport chamber 11 and the load-lock chambers 12.

The pre-cleaning apparatuses 21 and 22 are connected, respectively, to two side walls of the first substrate transport chamber 13 at the front side. The pre-cleaning apparatuses 21 and 22 perform a pre-cleaning process for removing a metal oxide as a pre-process for a process of embedding ruthenium. For example, the pre-cleaning apparatuses 21 and 22 remove a metal oxide that is a lower layer of a recess included in a substrate. When the lower layer of the recess included in the substrate is a tungsten layer, the pre-cleaning apparatuses 21 and 22 remove a tungsten oxide due to oxidation of tungsten. In addition, for example, when the lower layer of the recess in the substrate is a ruthenium layer, the pre-cleaning apparatuses 21 and 22 remove a ruthenium oxide formed due to oxidation of ruthenium. The pre-cleaning apparatuses 21 and 22 reduce and remove a metal oxide by hydrogen plasma obtained by turning hydrogen gas into plasma.

The film forming apparatuses 23 and 24 are connected, respectively, to two side walls of the first substrate transport chamber 13 at the rear side. The first transport mechanism 13a installed in the first substrate transport chamber 13 transports substrates among these four processing chambers PM 21 to 24, the delivery parts 17, and the load-lock chambers 12. In FIG. 1, reference numeral GV1 indicates gate valves.

The film forming apparatuses 25 and 26 are connected, respectively, to two side walls of the second substrate transport chamber 14 at the front side. In this example, the film forming apparatuses 25 and 26 are film forming apparatuses for embedding ruthenium.

The film forming apparatus 27 and the annealing apparatus 28 are connected, respectively, to two side walls of the second substrate transport chamber 14 at the rear side. Then, the second transport mechanism 14a transports substrates between these four processing chambers PM (25 to 28) and the delivery parts 17. In FIG. 1, the reference numerals GV2 and GV3 indicate gate valves, respectively. The film forming apparatus 27 is a film forming apparatus for laminating ruthenium.

In this example, the film forming apparatus 23 to 26 each embed ruthenium in a recess in a bottom-up manner by using a raw-material gas containing Ru₃(CO)₁₂ (hereinafter, also referred to as DCR) as a ruthenium raw-material. The film forming apparatus 27 forms ruthenium up to a field portion by using a raw-material gas containing DCR. This is a process of stacking ruthenium layers for a flattening process (CMP) in the next step.

The annealing apparatus 28 anneals the substrate after the ruthenium is formed up to the field portion. The annealing apparatus 28 may not perform the annealing. The annealing apparatus 28 is an apparatus capable of heating a substrate by a heating part such as a heater.

The film forming system 1 includes a controller 100 that controls the operation of each part constituting the film forming system 1, such as various processes in the pre-cleaning apparatuses 21 and 22, the film forming apparatuses 23 to 27, and the annealing apparatus 28, or substrate transportation. The controller 100 includes, for example, a computer having a CPU (not illustrated) and a memory (storage), and the memory stores a control program necessary for the operation of each part constituting the film forming system 1. The control program may be stored in a non-transient computer readable storage medium such as a hard disk, a compact disk, a magneto-optical disk, a memory card, or a non-volatile memory, and may be installed in the computer from the storage medium. The control program may be acquired from a network connected to the controller 100 by using communication means.

As described above as an example, the film forming system 1 includes at least one film forming apparatus for forming a ruthenium film, and the film forming apparatus is used to embed ruthenium in a substrate having a recess. In this example, the film forming apparatuses 23 to 27 have the same configuration, but the film forming apparatus 27 may not include some components of the film forming apparatuses 23 to 26 (an ozone gas supply line, a hydrogen-containing gas supply line, an ozone gas exhaust line, and the like, which will be described later).

### [Film Forming Apparatus]

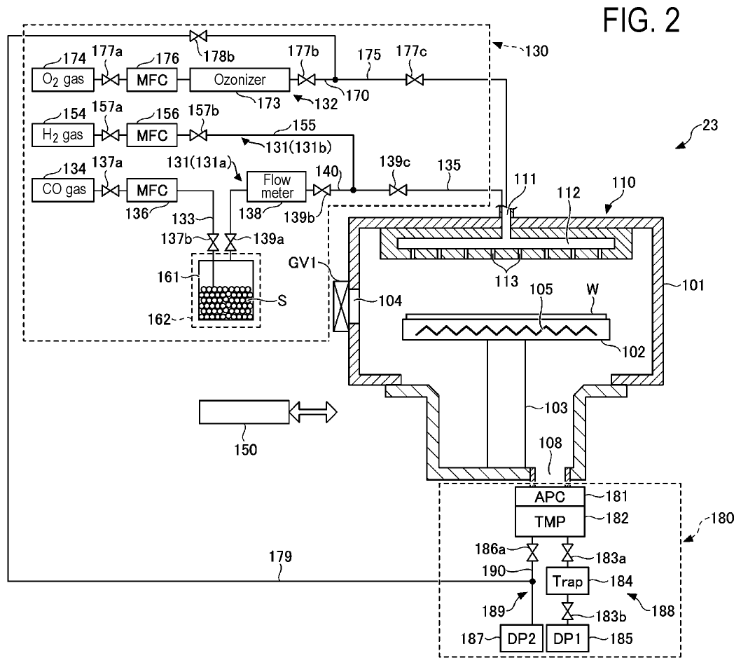

Next, the configuration of a film forming apparatus according to an embodiment included in the film forming system 1 will be described with reference to FIG. 2. Here, the configuration of the film forming apparatus 23 will be described as an example, and the description of the film forming apparatus 24 to 27 having the same configuration will be omitted. FIG. 2 is a schematic cross-sectional view illustrating an example of the film forming apparatus 23 according to an embodiment. The illustration of the configurations of the pre-cleaning apparatuses 21 and 22 and the annealing apparatus 28 are omitted.

The film forming apparatus 23 includes a processing container 101, and the side wall of the processing container 101 is connected to the first substrate transport chamber 13 and includes a transport port 104 for carry-in/out of a substrate to and from the first substrate transport chamber 13. The transport port 104 is configured to be openable/closable by the gate valve GV1.

In the processing container 101, a stage 102 configured to horizontally support a substrate W is installed in a state of being supported by a support pillar 103 from the bottom surface side of the stage 102. The stage 102 includes a heater 105 to be capable of heating the substrate W to a preset temperature.

A shower head 110 is disposed on the ceiling of the processing container 101 to face the substrate W placed on the stage 102. The shower head 110 includes a gas diffusion space 112, and gas ejection ports 113 are dispersedly formed in the bottom surface of the shower head 110.

In addition, the film forming apparatus 23 includes a gas supplier 130 for supplying gas and a gas exhauster 180 for exhausting gas. The gas supplier 130 includes a first supply line 131 for supplying a gas containing a ruthenium raw-material gas and a hydrogen-containing gas to the processing container 101, and a second supply line 132 for supplying a gas containing ozone gas. The first supply line 131 includes a raw-material gas supply line 131a for supplying a gas containing a ruthenium raw-material gas and a hydrogen gas supply line 131b for supplying a hydrogen-containing gas.

The raw-material gas supply line 131a includes a carrier gas supply pipe 133 and supply pipes 140 and 135. The carrier gas supply pipe 133 extends from a CO gas source 134 and is connected to a raw-material container 161. The end of the supply pipe 133 is provided to be inserted into a raw material S. The supply pipe 133 is provided with a valve 137a, a mass flow controller 136, and a valve 137b in this order from the CO gas source 134. CO gas is supplied to the raw-material container 161 as a carrier gas from the CO gas source 134 via the supply pipe 133. However, as the carrier gas, an inert gas such as argon (Ar) gas or nitrogen (N₂) gas may be used instead of the CO gas.

The raw-material container 161 accommodates the raw material S for ruthenium. In this example, DCR is accommodated in the raw-material container 161 as the raw material S for the ruthenium film, but the raw material S for the ruthenium film is not limited to DCR and may be an organic gas. The raw material S in the raw-material container 161 is heated by a heater 162 to be vaporized.

The raw-material container 161 and a gas introduction port 111 of the shower head 110 are connected to each other by the supply pipes 140 and 135. The upper end surface of the raw-material container 161 is connected to the supply pipe 140, and the supply pipe 140 is further connected to the supply pipe 135 and connected to the gas introduction port 111. The supply pipe 140 is provided with a valve 139a, a flow meter 138, and a valve 139b in this order from the raw-material container 161. The supply pipe 140 is provided with a valve 139c.

The ruthenium raw-material gas vaporized in the raw-material container 161 flows in the supply pipes 140 and 135 by using CO gas as a carrier gas, and is supplied to the processing container 101 from the gas introduction port 111. The flow meter 138 detects the flow rate of the raw-material gas. With this configuration, a ruthenium film is formed in a recess in the surface of a substrate W by the raw-material gas supplied from the first supply line 131 to the processing container 101.

When a ruthenium film can be formed from the bottom of the recess formed in the substrate W in a bottom-up manner, it is possible to avoid the generation of voids and seam to be described later so that a low resistance ruthenium layer can be formed. However, a ruthenium film (hereinafter, also referred to as a “ruthenium piece”) is formed on the side wall (side surface) of the recess during the film forming process. When the ruthenium piece formed on the side wall is removed by etching, the side surface of the recess is in the state in which no ruthenium film is formed, so that the generation of voids can be avoided. Therefore, in the film forming apparatus 23, ruthenium is grown in a bottom-up manner from the bottom of the recess by a DED method (deposition-etching-deposition method) of repeatedly executing the formation of the ruthenium film (D: deposition) and the removal of the ruthenium piece (E: etching).

When the DED method is not used, the ruthenium piece formed on the side wall of the recess closes the frontage of the recess, which may cause the generation of a void, or a minute gap (seam) may be generated in the recess by the film formation of a conformal ruthenium film. In the film forming method according to an embodiment to be described later, the DED method enables bottom-up embedding of ruthenium in a recess so that a ruthenium wire or contact can be implemented while avoiding a void and a seam.

Therefore, after forming a ruthenium film in the recess, a gas containing ozone is supplied from the second supply line 132 into the processing container 101, and the ruthenium piece formed on the side wall of the recess is etched and removed by the ozone gas.

The second supply line 132 includes supply pipes 170 and 175. The supply pipe 170 extends from the O₂ gas source 174 and is connected to the supply pipe 175. The supply pipe 175 is connected to the gas introduction port 111 for introducing O₂ gas. The supply pipe 170 is provided with a valve 177a, a mass flow controller 176, an ozonizer 173, and a valve 177b in this order from the O₂ gas source 174. The supply pipe 175 is provided with a valve 177c.

The oxygen gas supplied from the O₂ gas source 174 is supplied to the ozonizer 173 while the flow rate thereof is controlled by a mass flow controller 176. The ozonizer 173 discharges the oxygen gas by electric energy to produce ozone gas, controls the concentration of ozone gas relative to oxygen gas, and outputs a mixed gas of ozone gas and oxygen gas that is controlled to a certain concentration. The mixed gas of ozone gas and oxygen gas is an example of the gas containing ozone gas. The gas containing ozone gas is supplied to the processing container 101 through the supply pipe 175. As a result, the ruthenium piece formed on the side wall of the recess is etched and removed.

The first supply line 131 further includes a supply pipe 155 branched from the supply pipe 135. The supply pipe 155 extends from a H₂ gas source 154 and is connected to the supply pipe 135. The supply pipe 155 is provided with a valve 157a, a mass flow controller 156, and a valve 157b in this order from the H₂ gas source 154.

The flow rate of hydrogen (H₂) gas supplied from the H₂ gas source 154 is controlled by the mass flow controller 156. The hydrogen gas is an example of the hydrogen-containing gas. The hydrogen gas is supplied to the processing container 101 through the supply pipes 155 and 135. As a result, the ruthenium layer is modified (reduced) by the hydrogen-containing gas. In this example, hydrogen gas, which is a reducing gas, is used as a reaction gas. As the reaction gas, H₂ gas plasma, NH₃ gas, NH₃ plasma, monomethylhydrazine (MMH), hydrazine (N₂H₄), or the like may be used.

The gas exhauster 180 includes a first exhaust line 188 and a second exhaust line 189. The first exhaust line 188 and the second exhaust line 189 are connected to an exhaust pipe 108 provided in the bottom wall of the processing container 101 via a pressure adjuster (APC) 181 and a turbo molecular pump (TMP) 182.

The first exhaust line 188 includes an exhaust pipe. The exhaust pipe of the first exhaust line 188 extends from a dry pump (DP1) 185 and is connected to the turbo molecular pump (TMP) 182. The exhaust pipe of the first exhaust line 188 is provided with a valve 183b, a trap device 184, and a valve 183a in this order from the dry pump (DP1) 185 side. The dry pump (DP1) 185 roughly evacuates the interior of the processing container 101 and exhausts the residual gas of the ruthenium raw-material gas. At that time, the raw-material gas is recovered by the trap device 184. The turbo molecular pump 182 vacuumizes the interior of the processing container 101 while adjusting the pressure in the processing container 101 by the pressure adjuster 181. The first exhaust line 188 exhausts the residual gas of the ruthenium raw-material gas. In addition, the first exhaust line 188 exhausts the residual gas of the hydrogen-containing gas.

The second exhaust line 189 includes an exhaust pipe 190. The exhaust pipe 190 extends from the dry pump (DP2) 187 and is connected to the turbo molecular pump (TMP) 182. The exhaust pipe 190 is provided with a valve 186a. The dry pump (DP2) 187 roughly evacuates the interior of the processing container 101 and exhausts the residual gas of the gas containing ozone gas. The turbo molecular pump 182 vacuumizes the interior of the processing container 101 while adjusting the pressure in the processing container 101 by the pressure adjuster 181. The second exhaust line 189 exhausts the residual gas of the gas containing ozone gas.

In addition, the second exhaust line 189 includes a bypass exhaust line 179 that interconnects the second supply line 132 and the second exhaust line 189 without passing through the processing container 101. The bypass exhaust line 179 causes the gas containing ozone gas to flow from the second supply line 132 to the second exhaust line 189 during ruthenium film formation. The bypass exhaust line 179 is provided with a valve 178b.

The exhaust pipe 190 is an example of a second main exhaust line 190 that exhausts the gas containing ozone gas from the interior of the processing container 101.

The film forming apparatus 23 includes a controller 150 that controls the operation of each part constituting the film forming apparatus 23. The controller 150 includes, for example, a computer having a CPU (not illustrated) and a memory (a storage), and the memory stores a process recipe in which steps (commands) for control necessary for performing a film forming method to be described later are set. The process recipe may be stored in a non-transient computer readable storage medium such as a hard disk and installed in the computer from the storage medium, or may be acquired from a network connected to the controller 150 by using communication means. The controller 150 may control the film forming apparatus 23 and the film forming system 1 in cooperation with the controller 100.

### [Film Forming Method]

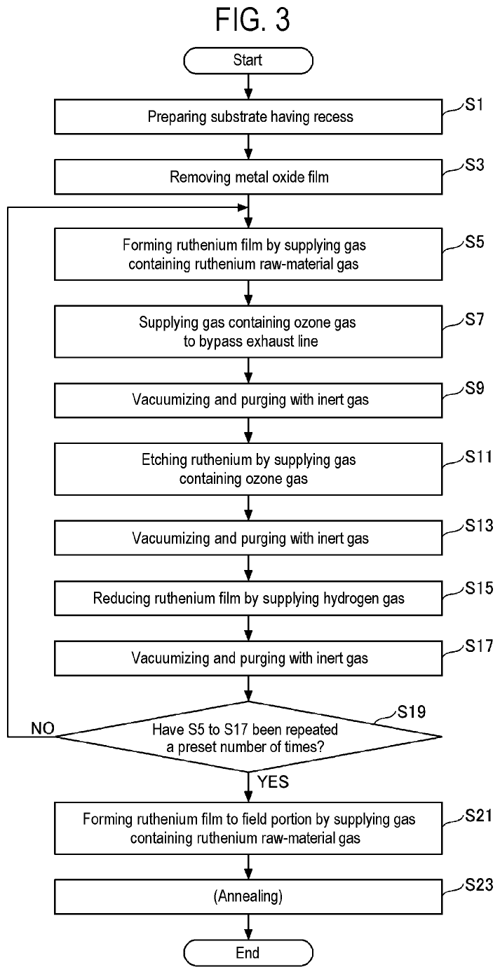

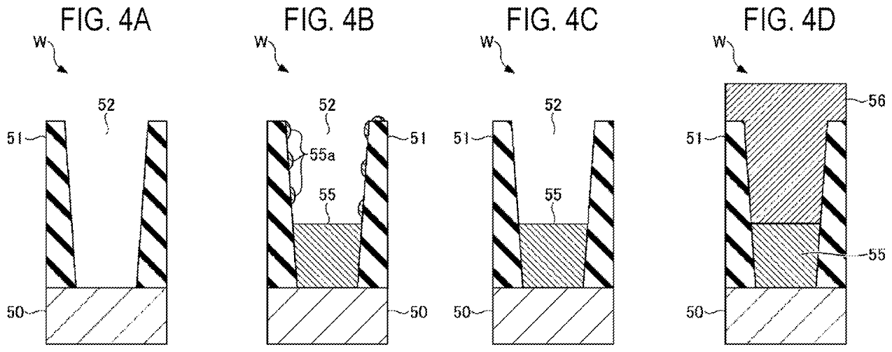

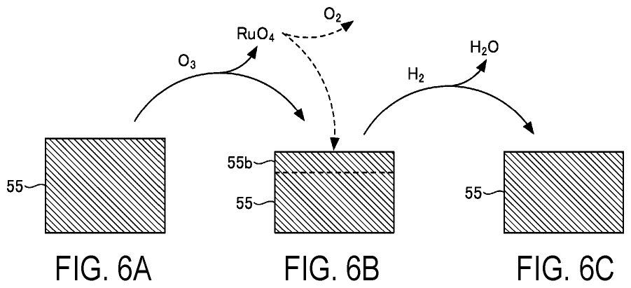

Next, an example of a film forming method according to an embodiment executed by the film forming system 1 will be described with reference to FIGS. 3 to 6C in addition to FIG. 1. FIG. 3 is a flowchart illustrating an example of a film forming method according to an embodiment. FIGS. 4A to 4D are cross-sectional views of a recess of a substrate in the film forming method of FIG. 3. FIGS. 6A to 6C are views illustrating chemical reactions that occur in the film forming method of FIG. 3.

### Substrate Preparation Step: Step S1

The film forming method illustrated in FIG. 3 is executed by cooperation of the controller 100 and/or the controller 150 or the like. For example, the controller 150 initiates this process according to a process recipe in response to commands from the controller 100. When this process is initiated, in step S1, the controller 100 carries a substrate W having a recess into any of the pre-cleaning apparatuses 21 and 22.

As illustrated in FIG. 4A, an insulating film having a recess 52, for example, a silicon oxide film (SiOₓ film) 51 is formed on the surface of the carried-in substrate W. The layer below the silicon oxide film 51 is a metal layer 50 of tungsten or the like. The metal layer 50 is exposed from the bottom of the recess 52, and the exposed metal layer 50 is oxidized to form a metal oxide film 50a.

In order to remove the metal oxide film 50a, the controller 100 first takes out the substrate accommodated in the carrier C by the atmospheric transport mechanism 11a illustrated in FIG. 1, delivers the substrate to a load-lock chamber 12 in an atmospheric pressure atmosphere, and adjusts the load-lock chamber 12 to a vacuum pressure atmosphere. Next, the controller 100 transports the substrate in the load-lock chamber 12 to any of the pre-cleaning apparatuses 21 and 22 by the first transport mechanism 13a, and performs the next pre-cleaning process.

### Pre-Cleaning Step: Step S3

Next, in step S3, the metal oxide film 50a at the bottom of the recess 52 illustrated in FIG. 4A is reduced and removed by hydrogen plasma obtained by controlling hydrogen gas to the following process conditions and turning the hydrogen gas into plasma. In this example, the metal oxide film 50a is a tungsten oxide film.

### <Pre-Cleaning Process Conditions>

Gas: H₂

Flow rate of H₂ gas: 2,000 sccm

Pressure in processing container: 5 Torr (667 Pa)

### Ruthenium Film Forming (Embedding) Step: Step S5

Next, the controller 100 transports the substrate to any of the film forming apparatuses 23 and 24 via the first transport mechanism 13a illustrated in FIG. 1, or to any of the film forming apparatuses 25 and 26 via the first transport mechanism 13a, a delivery part 17, and the second transport mechanism 14a.

In the film forming apparatus 23, the controller 150 forms a ruthenium layer in a region including the bottom of the recess 52. Specifically, the controller 150 carries the substrate into the processing container 101, places the substrate on the stage 102, heats the substrate with the heater 105, and evacuates the interior of the processing container 101 by the gas exhauster 180.

In step S5 of FIG. 3, the process conditions are controlled as follows, and as shown in FIG. 4B, ruthenium is embedded in a region including the bottom of the recess 52 with a vaporized ruthenium raw-material gas to form a ruthenium layer 55.

### <Ruthenium Embedding Process Conditions>

Gas: DCR raw-material gas, CO gas

Flow rate of CO gas: 100 sccm

Pressure in processing container: 16.6 mTorr (2.21 Pa)

Temperature of stage: 100 degrees C. to 200 degrees C.

In the raw material container 161 illustrated in FIG. 2, the DCR, which is the raw material S for ruthenium, is heated by the heater 162. The valves 137a and 137b provided in the carrier gas supply pipe 133 of the first supply line 131 are opened, and the CO gas, which is a carrier gas having a flow rate controlled by the mass flow controller 136, is supplied to the raw material container 161. The ruthenium raw-material gas is vaporized by heating with the heater 162. At this time, the valves 139a, 139b, and 139c provided in the supply pipes 140 and 135 are opened. As a result, the vaporized raw-material gas is supplied into the processing container 101, and a ruthenium layer 55 is formed in the recess 52.

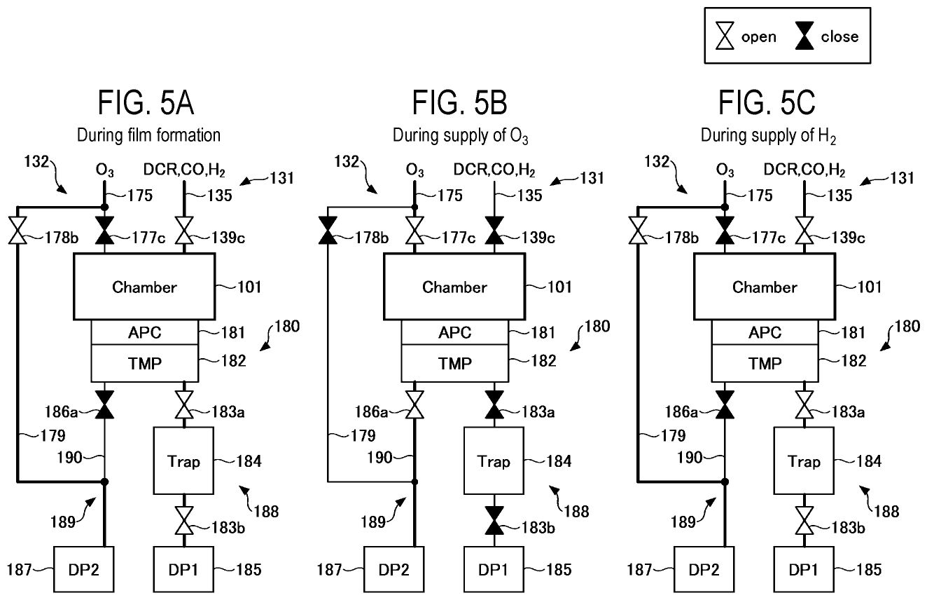

The operation of gas supply and gas exhaust in the ruthenium embedding step (during film formation) is illustrated in FIG. 5A. The valve 139c of the first supply line 131 is opened and the valve 177c of the second supply line 132 is closed. As a result, a gas containing the ruthenium raw-material gas is supplied into the processing container 101, and the ruthenium layer 55 is formed. During the film formation, the ruthenium film (hereinafter, also referred to as a “ruthenium piece 55a”) is partially formed on the side wall in the recess 52.

While the ruthenium film is being formed in step S5, the first exhaust line 188 exhausts the gas containing the ruthenium raw-material gas in the processing container 101. Specifically, as illustrated in FIG. 5A, the valves 183a and 183b of the first exhaust line 188 are opened, and the valve 186a of the second exhaust line 189 is closed. The first exhaust line 188 roughly evacuates the interior of the processing container 101 by using the dry pump (DP1) 185 and then vacuumizes the interior of the processing container 101 by using the pressure adjuster 181 and the turbo molecular pump 182, thereby exhausting the gas containing the ruthenium raw-material gas from the processing container 101. After a predetermined length of time has elapsed from the initiation of the process of step S5, the controller 150 closes the valve 139c to stop the supply of the gas containing the ruthenium raw-material gas.

### Bypass Exhaust Step: Step S7

Step S7 in FIG. 3 is executed in parallel with step S5. During the film formation of a ruthenium layer in step S5, in step S7, the controller 150 exhausts the gas containing ozone from the bypass exhaust line 179. At this time, the valves 177a and 177b of the second supply line 132 are opened. In addition, as illustrated in FIG. 5A, the valve 178b of the bypass exhaust line 179 is opened and the valve 177c of the supply pipe 175 is closed to allow the gas containing ozone gas to flow to the bypass exhaust line 179 without passing through the processing container 101, and the gas containing ozone gas is exhausted by using a dry pump (DP2) 187. At this time, the valve 186a of the second exhaust line 189 is closed. In addition, the valves 157a and 157b of the hydrogen gas supply line 131b illustrated in FIG. 1 are closed.

### Vacuumizing Step: Step S9

Next, in step S9 of FIG. 3, the interior of the processing container 101 is vacuumized by using the exhaust apparatus of the first exhaust line 188. As a result, the gas containing the ruthenium raw-material gas is exhausted. In step S9, purge may be performed together with the above-mentioned vacuumizing. In the purge step, an inert gas such as Ar gas or N₂ gas is supplied into the processing container 101, and the gas containing the ruthenium raw-material gas in the processing container 101 is replaced with the inert gas.

### Ruthenium Etching Step: Step S11

Next, in step S11 of FIG. 3, the process conditions are controlled as follows, and the ruthenium piece 55a that has adhered to the side wall of the recess 52 is etched and removed.

### <Etching Process Conditions>

Gas: Mixed gas of O₃ and O₂

Flow rate of O₃ gas): 300 g/m³

Pressure in processing container: 3 Torr (400 Pa)

Temperature of stage: 100 degrees C. to 200 degrees C.

As illustrated in FIG. 2 and FIG. 5B, in step S11, the valve 139c of the first supply line 131 is closed. In addition, the valve 178b of the bypass exhaust line 179 is closed. The valve 177c of the second supply line 132 is opened. The valves 177a and 177b of the second supply line 132 remain open. In the second supply line 132, the mixed gas of O₃ and O₂ having a predetermined concentration and output from the ozonizer 173 is supplied into the processing container 101. As a result, a gas containing ozone gas is supplied into the processing container 101, the ruthenium layer 55 and the ruthenium piece 55a illustrated in FIG. 4B are etched, and the ruthenium piece 55a is etched and removed from the side wall of the recess 52 as illustrated in FIG. 4C. In addition, the valves 183a and 183b of the first exhaust line 188 are closed, and the valves 186a of the second exhaust line 189 are opened. As a result, the residual gas of the gas containing ozone gas is exhausted from the second exhaust line 189.

In step S11, the state in which the valve 178b is opened and the valve 177c and 186a are closed, as illustrated in FIG. 5A, is switched into the state in which the valve 178b is closed and the valve 177c and 186a are opened, as illustrated in FIG. 5B. As a result, the gas containing ozone gas can be stably supplied from the second supply line 132 into the processing container 101. The residual gas of the gas containing ozone gas in the processing container 101 is exhausted from the second exhaust line 189. After a predetermined length of time has elapsed from the initiation of the process of step S11, the controller 150 closes the valve 177c to stop the supply of the gas containing ozone gas to the processing container 101.

### Vacuumizing Step: Step S13

In step S13, the interior of the processing container 101 is vacuumized by using the exhaust apparatus of the second exhaust line 189. As a result, the gas containing ozone gas is exhausted. Purge may be performed together with the above-mentioned vacuumizing. In the purge step, an inert gas is supplied into the processing container 101, and the gas containing ozone gas in the processing container 101 is replaced with the inert gas.

### Ruthenium Reduction Step: Step S15

Next, in step S15 of FIG. 3, the valve 157a, the valve 157b, and the valve 139c of the first supply line 131 (the hydrogen gas supply line 131b) are opened. In the first supply line 131 (the hydrogen gas supply line 131b), hydrogen gas, which is output from the H₂ gas source 154 and has a flow rate controlled by the mass flow controller 156, is supplied into the processing container 101.

In step S15, the ruthenium layer 55 is modified (reduced) by supplying a hydrogen-containing gas, which is controlled to the following process conditions, from the hydrogen gas supply line 131b into the processing container 101.

### <Modification (Reduction) Process Conditions>

Gas: H₂ gas

Flow rate of H₂ gas: 2,000 sccm

Pressure in processing container: 5 Torr

Temperature of stage: 100 degrees C. to 200 degrees C.

This makes it possible to reduce and return a ruthenium oxide layer formed on the surface layer of the ruthenium layer 55 into the ruthenium layer 55. During the supply of H₂ gas, as illustrated in FIG. 5C, the valve 186a is closed and the valves 183a and 183b are opened, so that the hydrogen-containing gas in the processing container 101 is exhausted from the first exhaust line 188. In addition, the controller 150 opens the valve 178b and closes the valves 177c and 186a to exhaust the gas containing ozone gas from the bypass exhaust line 179. By switching the exhaust line from the second exhaust line 189 to the first exhaust line 188, it is possible to ensure safety by avoiding exhausting ozone gas and hydrogen gas from the same exhaust line, and thus avoiding the danger that the ozone gas reacts with the hydrogen gas and explodes.

At this time, the valve 139b of the raw-material gas supply line 131a is closed. As illustrated in FIG. 5C, the valves 183a and 183b of the first exhaust line 188 are opened, and the residual gas of hydrogen gas is exhausted from the first exhaust line 188. In addition, the valve 178b of the bypass exhaust line 179 is open, and the valve 186a is closed. As a result, the gas containing ozone gas flows through the bypass exhaust line 179 and is exhausted by the dry pump (DP2) 187. After a predetermined length of time has elapsed from the initiation of the process of step S15, the valve 139c is closed and the supply of hydrogen gas is stopped.

### Vacuumizing Step: Step S17

Next, in step S17 of FIG. 3, the interior of the processing container 101 is vacuumized from the first exhaust line 188. As a result, the hydrogen-containing gas is exhausted. In step S17, purge may be performed together with the above-mentioned vacuumizing. In the purge step, an inert gas is supplied into the processing container 101, and the hydrogen-containing gas in the processing container 101 is replaced with the inert gas.

### Determination Step: Step S19

Next, the controller 150 determines whether the ruthenium embedding process (steps S5 to S17) has been executed a predetermined set number of times. When the controller 150 determines that the ruthenium embedding process has not been executed the set number of times, the controller 150 returns to step S5 and executes steps S5 to S17. As a result, the film formation illustrated in FIG. 4B and the etching illustrated in FIG. 4C are repeated the set number of times. This makes it possible to perform the film formation and the etching of ruthenium with the same film forming apparatus.

When the controller 150 determines that the ruthenium embedding process has been executed the set number of times, the substrate W is carried out, and the controller 100 transmits the substrate to the film forming apparatus 27 via the first transport mechanism 13a, the delivery part 17, and the second transport mechanism 14a.

### Ruthenium Film Forming (Laminating) Step: Step S21

Next, in step S21 of FIG. 3, a ruthenium layer 56 is laminated on the field portion of the upper layer of the ruthenium layer 55 formed at the bottom of the recess 52 by a ruthenium raw-material gas controlled to the following process conditions and vaporized. As a result, as illustrated in FIG. 4D, the ruthenium layer 56 is formed on the ruthenium layer 55 embedded in the recess of the substrate W. The opening and closing of each valve is the same as that during the embedding ruthenium in step S5. However, the process conditions may be different from those in step S5. The temperature of the stage may be higher than that in step S5.

### <Ruthenium Laminating Process Conditions>

Gas: DCR raw-material gas, CO gas

Flow rate of CO gas: 100 sccm

Pressure in processing container: 16.6 mTorr (2.21 Pa)

Temperature of stage: 100 degrees C. to 250 degrees C.

### Annealing Step: Step S23

Next, when annealing the formed ruthenium layer, the controller 100 transports the substrate to the annealing apparatus 28 via the second transport mechanism 14a, and the annealing apparatus 28 is controlled to the following process conditions and heats the transported wafer W at a predetermined temperature. Thereafter, this process is terminated.

### <Annealing Process Conditions>

Gas: N₂ gas

Flow rate of CO gas: 100 sccm

Pressure in processing container: 5 Torr

Temperature of stage: 300 degrees C. to 500 degrees C.

The actions of the film forming method described above will be described with reference to FIGS. 6A to 6C. FIGS. 6A to 6C are schematic views illustrating chemical reactions that occur in steps S5 to S17 of the film forming method of FIG. 3. FIG. 6A illustrates the case where, with respect to the ruthenium layer 55 formed in the recess of the substrate in step S5 of FIG. 3, the gas containing ozone gas is supplied in step S11 of FIG. 3. The chemical reaction (1), which is one of the reactions between the ruthenium layer 55 and ozone gas in this case, is represented by Ru+2/3O₃→RuO₂. In this chemical reaction (1), Gibbs free energy is −345 kJ/mol, and the chemical reaction (1) proceeds. As illustrated in FIG. 6B, the surface of the ruthenium layer 55 is oxidized to form a ruthenium oxide layer 55b of RuO₂.

In addition, the chemical reaction (2), which is one of the reactions between the ruthenium layer 55 and ozone gas, is represented by Ru+4/3O₃→Rua′. In this chemical reaction (2), Gibbs free energy is −350 kJ/mol, and the chemical reaction (2) proceeds.

In addition, the chemical reaction (3) between the ruthenium oxide layer (RuO₂) 55b and ozone gas is represented by RuO₂+2/3O₃→RuO₄. In this chemical reaction (3), Gibbs free energy is −5.36 kJ/mol, and a reaction is unlikely to occur, but the chemical reaction (2) occurs. RuO₄ formed by these chemical reactions (2) and (3) is volatized. As a result, as illustrated in FIGS. 6A and 6B, the surface of the ruthenium layer 55 and the ruthenium piece 55a (see FIG. 4B) are etched and removed.

The chemical reaction (4) for reducing the remaining ruthenium oxide layer 55b with hydrogen gas is represented by RuO₂+2H₂→Ru+H₂O. In this chemical reaction (4), Gibbs free energy is −215 kJ/mol, and the chemical reaction (4) proceeds. As a result, as illustrated in FIG. 6C, the ruthenium oxide layer 55b is reduced by hydrogen gas to return to the ruthenium layer 55. H₂O is volatilized.

From the foregoing, in the film forming method according to the present embodiment, after forming a ruthenium layer, a gas containing ozone gas is supplied in the same film forming apparatus, and film formation and etching of Ru are repeated so that the ruthenium layer can be formed in a recess of a substrate in a bottom-up manner without generating a void. In addition to the film formation and etching of Ru, by reducing a RuOₓ film by supplying a hydrogen-containing gas in the same film forming apparatus, it is possible to form a ruthenium layer having a lower resistance.

In the film forming method of FIG. 3, the lines for supplying and exhausting a gas containing ozone gas (the second supply line 132 and a second exhaust line 189) and the lines for supplying and exhausting a hydrogen-containing gas (the first supply line 131 and the first exhaust line 188) are provided as separate lines. This is because when ozone gas and hydrogen gas are supplied to the same supply line and exhaust line, there is a danger that ozone gas and hydrogen gas react and explode. The hydrogen-containing gas supply line is the same as the supply line for supplying the gas containing the ruthenium raw-material gas.

During the step of supplying the gas containing the ruthenium raw-material gas (step S5), the gas containing ozone gas is exhausted by the dry pump (DP2) 187 through the bypass exhaust line 179. Since ozone gas is generated by discharging oxygen gas, in order to stabilize the discharge, it is necessary to keep the ozone gas flowing even during the film formation of ruthenium to stabilize the flow rate and concentration of the ozone gas. Therefore, in the film forming method according to the present embodiment, when ozone gas is not used for processing in the processing container 101, for example, when forming a ruthenium film, the gas containing ozone gas is caused to continuously flow through the bypass exhaust line 179. This makes it possible to stabilize the flow rate and concentration of ozone gas. The continuous flowing is necessary.

In the film forming method of FIG. 3, the ruthenium film forming (step S5), the step of supplying a gas containing ozone gas (the ruthenium etching step: step S11), and the step of supplying a hydrogen-containing gas (the ruthenium reduction step: step S15) are repeatedly executed in this order.

However, respective steps are not limited to repeating in this order. For example, after executing the ruthenium film forming step, the ruthenium etching step and the ruthenium reduction step may be repeated multiple times, and then the process may return to the ruthenium film forming step.

When the ruthenium etching step and the ruthenium reduction step are repeated multiple times after executing the ruthenium film forming step, the ruthenium etching step may be divided into plural times and the gas containing ozone gas may be intermittently supplied multiple times. According to this, since the gas containing ozone gas having a certain flow rate is stored in a separate chamber and then supplied multiple times, it is possible to inject the high-pressure ozone gas into the processing container 101, and the ozone gas easily reaches the bottom of the recess. This enables the formation of a ruthenium film with higher embedding performance.

In the film forming method of FIG. 3, the purge processes of steps S9, S13, and S17 may be omitted, and only the vacuumizing process may be performed. The configuration of the film forming apparatus illustrated in FIGS. 2 and 5A to 5C corresponds to the configuration of the film forming apparatus according to the first embodiment.

### Second Embodiment

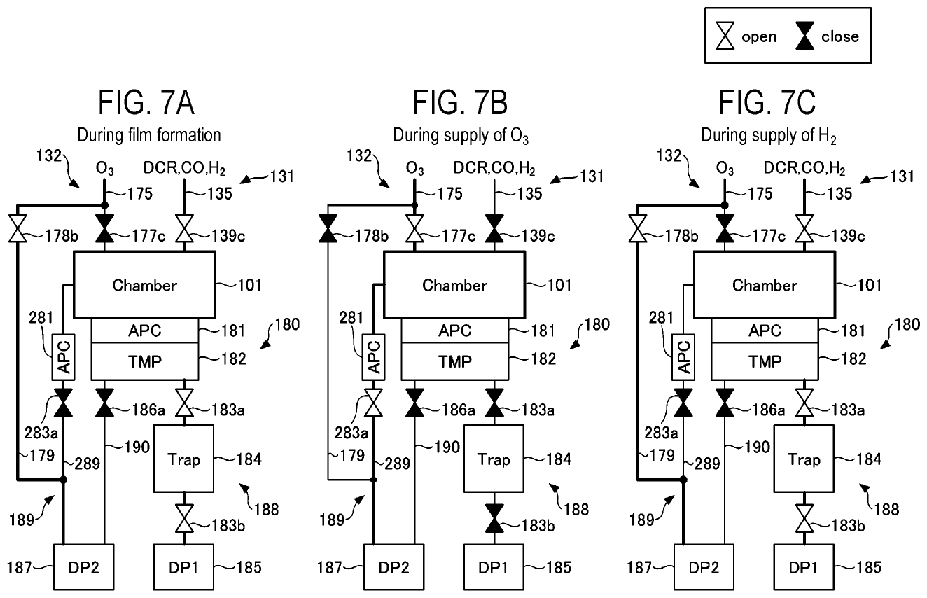

Hereinafter, the configuration and operation of a film forming apparatus according to a second embodiment will be described with reference to FIGS. 7A to 7C. FIGS. 7A to 7C is a view illustrating the configuration and operation of a film forming apparatus according to a second embodiment.

The configuration that differs from the first embodiment is that a new exhaust line is provided in the second exhaust line 189. The exhaust pipe 190 will also be referred to as a second main exhaust line 190. The second exhaust line 189 includes, as a line separate from the second main exhaust line 190, an exhaust pipe 289 that connects the processing container 101 and the dry pump (DP2) 187 to each other and exhausts a gas containing ozone gas from the processing container 101. The exhaust pipe 289 will also be referred to as a second sub-exhaust line 289. That is, the film forming apparatus according to the second embodiment is different from the film forming apparatus according to the first embodiment in that the second exhaust line 189 further includes the second sub-exhaust line 289. In other configurations, the film forming apparatus according to the second embodiment is the same as the film forming apparatus according to the first embodiment. The film forming apparatus according to the second embodiment does not have to be provided with the second main exhaust line 190. The bypass exhaust line 179 is connected to the exhaust pipe 289 of the second sub-exhaust line.

Hereinbelow, the configuration of the second sub-exhaust line 289 will be mainly described. The second sub-exhaust line 289 includes, between the processing container 101 and the dry pump (DP2) 187, a pressure adjuster 281 without including an evacuation apparatus that enables vacuumizing, such as a turbo molecular pump. The pressure adjuster 281 is connected to an exhaust pipe (not illustrated) provided in the side wall or bottom wall of the processing container 101.

The opened/closed state of each valve is the same during the film formation (embedding) of ruthenium in FIG. 7A and during the supply of hydrogen in FIG. 7C. That is, the valve 139c of the first supply line 131 is opened, and the valve 177c of the second supply line 132 is closed. As a result, during the film formation of ruthenium in FIG. 7A, a gas containing a ruthenium raw-material gas is supplied from the first supply line 131 into the processing container 101, and during the supply of hydrogen in FIG. 7C, a hydrogen-containing gas is supplied into the processing container 101 from the first supply line 131.

In addition, the valves 183a and 183b of the first exhaust line 188 are opened, and the valve 178b of the bypass exhaust line 179 of the second exhaust line 189 is opened. The valve 186a of the second main exhaust line 190 of the second exhaust line 189 and the valve 283a of the second sub-exhaust line 289 are closed. As a result, the gas containing the ruthenium raw-material gas is exhausted from the first exhaust line 188 during the ruthenium film formation in FIG. 7A, and the hydrogen-containing gas is exhausted from the first exhaust line 188 during the supply of supply in FIG. 7C. During these periods, the gas containing ozone gas is exhausted through the bypass exhaust line 179 without passing through the processing container 101.

During the supply of ozone gas in FIG. 7B, the valve 177c of the second supply line 132 and the valve 283a of the second sub-exhaust line 289 are opened, and the other valves 139c, 178b, 183a, 183b, and 186a are closed. As a result, during the supply of ozone gas, i.e., during the ruthenium etching, the gas containing ozone gas is supplied from the second supply line 132, and the gas containing ozone gas is exhausted from the second sub-exhaust line 289.

With the film forming apparatus according to the second embodiment, as in the film forming apparatus according to the first embodiment, after the ruthenium layer is formed in the same film forming apparatus, the supply of the gas containing ozone gas and the supply of the hydrogen-containing gas are repeated. As a result, the film formation and etching of Ru are repeated, so that a ruthenium layer can be formed in a recess of a substrate in a bottom-up manner without generating a void.

In addition, with the film forming apparatus according to the second embodiment, when supplying ozone gas, it is possible to cause the gas containing ozone gas to pass from the pressure adjuster 381 to the dry pump (DP2) 187 without causing the gas containing ozone gas to flow through the turbo molecular pump 182. The flow rate of gas that is capable of flowing through the turbo molecular pump 182 is limited to be less than the flow rate of gas that is capable of flowing through the dry pump (DP2) 187. Therefore, with the film forming apparatus according to the second embodiment, it is possible to use a relatively large flow rate of ozone gas.

### Third Embodiment

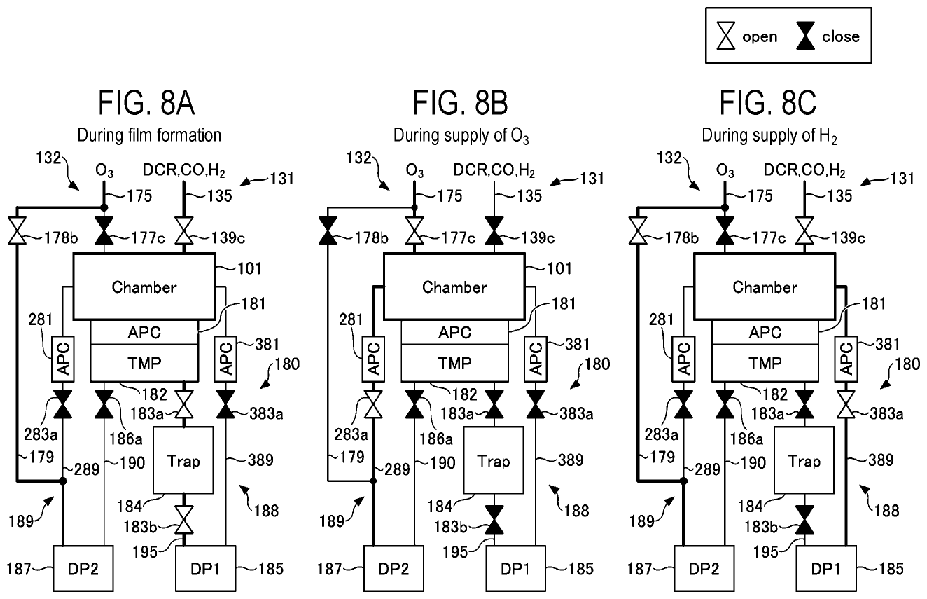

Next, the configuration and operation of a film forming apparatus according to a third embodiment will be described with reference to FIGS. 8A to 8C. FIGS. 8A to 8C is a view illustrating the configuration and operation of a film forming apparatus according to a third embodiment.

The configuration that differs from the second embodiment is that a new exhaust line is provided in the first exhaust line 188. The exhaust pipe 195 of the first exhaust line 188 will also be referred to as a first main exhaust line 195. The first exhaust line 188 includes, as a line separate from the first main exhaust line 195, an exhaust pipe 389 that connects the processing container 101 and the dry pump (DP1) 185 to each other and exhausts a gas containing a raw-material gas and a hydrogen-containing gas from the processing container 101. The exhaust pipe 389 will also be referred to as a first sub-exhaust line 389. That is, the film forming apparatus according to the third embodiment is different from the film forming apparatus according to the second embodiment in that the first exhaust line 188 further includes the first sub-exhaust line 389. In other configurations, the film forming apparatus according to the third embodiment is the same as the film forming apparatus according to the second embodiment. The film forming apparatus according to the third embodiment does not have to be provided with the second main exhaust line 190.

Hereinbelow, the configuration of the first sub-exhaust line 389 will be mainly described. The second sub-exhaust line 289 includes, between the processing container 101 and the dry pump (DP1) 185, a pressure adjuster 381 without including an evacuation apparatus that enables vacuumizing, such as a turbo molecular pump. The pressure adjuster 381 is connected to an exhaust pipe (not illustrated) provided in the side wall or bottom wall of the processing container 101.

In the film forming apparatus according to the third embodiment, during the film formation (embedding) of ruthenium in FIG. 8A, the valve 139c of the first supply line 131 is opened, and the valve 177c of the second supply line 132 is closed. As a result, a gas containing a ruthenium raw-material gas is supplied into the processing container 101 at the time of film formation. During the film formation of ruthenium in FIG. 8A, the valves 183a and 183b of the first main exhaust line 195 are opened, and the valve 383a of the first sub-exhaust line 389 is closed. Therefore, the gas containing the ruthenium raw-material gas is exhausted from the first main exhaust line 195.

At this time, the valve 178b of the bypass exhaust line 179 is opened, and the valve 186a of the second main exhaust line 190 and the valve 283a of the second sub-exhaust line 289 are closed. Therefore, a gas containing ozone gas is exhausted through the bypass exhaust line 179.

During the supply of ozone gas in FIG. 8B, the valve 139c of the first supply line 131 is closed, and the valve 177c of the second supply line 132 is opened. As a result, the supply of the gas containing the ruthenium raw-material gas is stopped, and the gas containing ozone gas is supplied into the processing container 101. The valves 183a and 183b of the first main exhaust line 195 are closed, and the valve 383a of the first sub-exhaust line 389 is closed. In addition, the valve 186a of the second main exhaust line 190 is closed, and the valve 283a of the second sub-exhaust line 289 is opened. The valve 178b of the bypass exhaust line 179 is closed. Therefore, the gas containing ozone gas is exhausted from the second sub-exhaust line 289.

During the supply of hydrogen in FIG. 8C, the valve 139c of the first supply line 131 is opened, and the valve 177c of the second supply line 132 is closed. As a result, the supply of the gas containing ozone gas is stopped, and the hydrogen-containing gas is supplied into the processing container 101. The valves 183a and 183b of the first main exhaust line 195 are closed, and the valve 383a of the first sub-exhaust line 389 is opened. Therefore, the hydrogen-containing gas is exhausted from the first sub-exhaust line 389.

At this time, the valve 178b of the bypass exhaust line 179 is opened, and the valve 186a of the second main exhaust line 190 and the valve 283a of the second sub-exhaust line 289 are closed. Therefore, the gas containing ozone gas is exhausted through the bypass exhaust line 179.

With the film forming apparatus according to the third embodiment, as in the film forming apparatuses according to the first and second embodiments, after the ruthenium layer is formed in the same film forming apparatus, the supply of the gas containing ozone gas and the supply of the hydrogen-containing gas are repeated. As a result, the film formation and etching of Ru are repeated, so that a ruthenium layer can be formed in a recess of a substrate in a bottom-up manner without generating a void.

In addition, with the film forming apparatus according to the third embodiment, when supplying the gas containing ozone gas, the gas containing ozone gas is exhausted from the second sub-exhaust line 289, and when supplying the hydrogen-containing gas, the hydrogen-containing gas is exhausted from the first sub-exhaust line 389. Accordingly, with the film forming apparatus according to the third embodiment, when supplying the gas containing ozone gas, it is possible to cause the gas containing ozone gas to pass from the pressure adjuster 381 to the dry pump (DP2) 187 without causing the gas containing ozone gas to flow through the turbo molecular pump 182. In addition, when supplying hydrogen gas, it is possible to cause hydrogen gas to pass from the pressure adjuster 381 to the dry pump (DP1) 185 without causing the hydrogen gas to flow through the turbo molecular pump 182. The flow rate of gas that is capable of flowing through the turbo molecular pump 182 is limited to be less than the flow rate of gas that is capable of flowing through the dry pump (DP1) 185 and the dry pump (DP2) 187. Therefore, with the film forming apparatus according to the third embodiment, it is possible to use a relatively large flow rate of ozone gas, and to use a relatively large flow rate of hydrogen gas.

Furthermore, with the film forming apparatus according to the third embodiment, in the film forming method in which the supply of ozone gas and the supply of hydrogen-containing gas are repeated once or multiple times during the film formation of ruthenium, it is possible to improve throughput by switching the supply of ozone gas and the supply of hydrogen-containing gas at high speed. The reason is that the exhaust amounts of the dry pumps DP1 and DP2 and the turbo molecular pump TMP are different. Therefore, when an exhaust line passing through a turbo molecular pump is used to supply the gas containing ozone gas and the hydrogen-containing gas, it takes time to stabilize the pressure. Since the dry pump DP1 and the dry pump DP2 have the same or similar exhaust amounts, at the time of switching between the gas containing ozone gas and the hydrogen-containing gas when the supply of the gas containing ozone gas and the supply of the hydrogen-containing gas are repeated, the pressure change in the processing container 101 is small so that the pressure can be controlled in the same order. Therefore, with the film forming method using the apparatus according to the third embodiment, it does not take time to stabilize the pressure in the processing container 101 only by switching between the opening and closing of the valve 283a and the valve 383a. As a result, it is possible to shorten the film formation time of a ruthenium layer so that the throughput can be improved.

As described above, according to the film forming apparatus, the film forming method, and the film forming system of the present embodiment, it is possible to execute the film formation and etching of ruthenium in the same film forming apparatus, and to embed the ruthenium in a bottom-up manner.

It should be considered that the film forming apparatuses, film forming methods, and the film forming systems according to the embodiments disclosed herein are exemplary in all aspect and are not restrictive. The embodiments may be modified and improved in various forms without departing from the scope and spirit of the appended claims. The matters described in the above embodiments may take other configurations within the non-contradictory range, and may be combined within the non-contradictory range.

For example, in the film forming apparatus of the present disclosure, it is also possible to clean the processing container 101 when supplying a gas containing ozone gas. By the ozone gas supplied from the ozonizer 173 to the processing container 101, it is possible to perform not only etching of ruthenium that has adhered to the side wall of a recess, but also cleaning of ruthenium deposited on a wall surface or the like of the processing container 101.

According to an aspect, it is possible to execute film formation and etching of ruthenium in the same film forming apparatus, and to embed ruthenium in a bottom-up manner

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus that embeds ruthenium in a substrate having a recess, the film forming apparatus comprising:
a processing container;
a gas supplier configured to supply gas; and
a gas exhauster configured to exhaust gas,
wherein the gas supplier includes a first supply line configured to supply a ruthenium raw-material gas into the processing container and a second supply line configured to supply a gas containing ozone gas into the processing container, and
wherein the gas exhauster includes a first exhaust line including a first exhaust apparatus and configured to exhaust a gas containing the ruthenium raw-material gas from an interior of the processing container by using the first exhaust apparatus, and a second exhaust line including a second exhaust apparatus different from the first exhaust apparatus and configured to exhaust the gas containing ozone gas by using the second exhaust apparatus.

2. The film forming apparatus of claim 1, wherein the second exhaust line includes a bypass exhaust line configured to interconnect the second supply line and the second exhaust apparatus without passing through the processing container, and exhaust the gas containing ozone gas.

3. The film forming apparatus of claim 2, wherein the second exhaust line includes a second main exhaust line configured to interconnect the processing container and the second exhaust apparatus, and exhaust the gas containing ozone gas from the interior of the processing container.

4. The film forming apparatus of claim 3, wherein the second main exhaust line includes a pressure adjuster and a vacuum exhaust apparatus between the processing container and the second exhaust apparatus.

5. The film forming apparatus of claim 3, wherein the second exhaust line includes a second sub-exhaust line that is a line separate from the second main exhaust line, the second sub-exhaust line being configured to interconnect the processing container and the second exhaust apparatus, and exhaust the gas containing ozone gas from the processing container.

6. The film forming apparatus of claim 5, wherein the second sub-exhaust line includes, between the processing container and the second exhaust apparatus, a pressure adjuster without including a vacuum exhaust apparatus.

7. The film forming apparatus of claim 1, wherein the first exhaust line includes a first main exhaust line configured to interconnect the processing container and the first exhaust apparatus, and a first sub-exhaust line that is separate from the first main exhaust line and is configured to interconnect the processing container and the first exhaust apparatus, and
wherein while the first supply line supplies a hydrogen-containing gas into the processing container, the first sub-exhaust line exhausts the hydrogen-containing gas from the processing container.

8. The film forming apparatus of claim 7, wherein the first main exhaust line includes a pressure adjuster and a vacuum exhaust apparatus between the processing container and the first exhaust apparatus, and
wherein the first sub-exhaust line includes, between the processing container and the first exhaust apparatus, a pressure adjuster without including a vacuum exhaust apparatus.

9. A film forming method of embedding ruthenium in a substrate having a recess by being executed by the film forming apparatus of claim 1, the film forming method comprising:
(a) a step of preparing the substrate in the processing container;
(b) a step of supplying a gas containing the ruthenium raw-material gas from the first supply line into the processing container to form a ruthenium layer, and exhausting the gas containing the ruthenium raw-material gas in the processing container from the first exhaust line;
(c) a step of supplying a gas containing ozone gas from the second supply line into the processing container to etch the ruthenium layer, and exhausting the gas containing ozone gas in the processing container from the second exhaust line different from the first exhaust line; and
(d) a step of supplying a hydrogen-containing gas into the processing container from the first supply line to modify the ruthenium layer, and exhausting the hydrogen-containing gas in the processing container from the first exhaust line.

10. The film forming method of claim 9, wherein the second exhaust line includes a bypass exhaust line configured to interconnect the second supply line and the second exhaust apparatus without passing through the processing container, and
during the step (b), the gas containing ozone gas is supplied from the second supply line and exhausted from the bypass exhaust line without passing through the processing container.

11. The film forming method of claim 10, wherein the second exhaust line includes a second main exhaust line configured to interconnect the processing container and the second exhaust apparatus, and the second main exhaust line includes a pressure adjuster and a vacuum exhaust apparatus between the processing container and the second exhaust apparatus, and
wherein the film forming method further comprises, during the step (c), a step of performing switching from the bypass exhaust line to the second main exhaust line to exhaust the gas containing ozone gas from the processing container.

12. The film forming method of claim 10, wherein the second exhaust line includes a second sub-exhaust line configured to interconnect the processing container and the second exhaust apparatus, and the second sub-exhaust line includes, between the processing container and the second exhaust apparatus, a pressure adjuster without including a vacuum exhaust apparatus, and
wherein the film forming method further comprises, during the step (c), a step of performing switching from the bypass exhaust line to the second sub-exhaust line to exhaust the gas containing ozone gas from the processing container.

13. The film forming method of claim 12, wherein the first exhaust line includes a first main exhaust line configured to interconnect the processing container and the first exhaust apparatus, and a first sub-exhaust line that is separate from the first main exhaust line and is configured to interconnect the processing container and the first exhaust apparatus,
wherein the first main exhaust line includes a pressure adjuster and a vacuum exhaust apparatus between the processing container and the first exhaust apparatus,
wherein the first sub-exhaust line includes, between the processing container and the first exhaust apparatus, a pressure adjuster without including a vacuum exhaust apparatus, and
wherein, when a predetermined condition is satisfied, switching between the first main exhaust line and the first sub-exhaust line is performed to exhaust the gas containing the ruthenium raw-material gas or the hydrogen-containing gas.

14. The film forming method of claim 13, wherein, when the switching from the bypass exhaust line to the second sub-exhaust line is performed to exhaust the gas containing ozone gas, it is determined that the predetermined condition is satisfied, the gas containing the ruthenium raw-material gas is exhausted from the first main exhaust line, and the hydrogen-containing gas is exhausted from the first sub-exhaust line.

15. The film forming method of claim 9, wherein the steps (b), (c), and (d) are repeatedly executed.

16. The film forming method of claim 9, wherein the steps (b), (c), and (d) are executed in the same film forming apparatus.

17. A film forming system comprising at least one film forming apparatus defined in claim 1, wherein the film forming system executes a process including a process of embedding ruthenium in a substrate having a recess by using the film forming apparatus.

18. The film forming system of claim 17, further comprising:
a pre-cleaning apparatus configured to execute a process of removing an oxide on a substrate,
wherein the film forming system removes a metal oxide on the substrate by using the pre-cleaning apparatus before the process of embedding the ruthenium.

19. The film forming system of claim 17, wherein the film forming system further laminates a ruthenium layer on the ruthenium embedded in the recess of the substrate after performing the process of embedding the ruthenium by using the film forming apparatus.

20. The film forming system of claim 19, further comprising:
an annealing apparatus configured to execute a process of annealing the substrate,
wherein the substrate subjected to the process of embedding the ruthenium or the substrate laminated with the ruthenium layer is annealed by using the annealing apparatus.
